(19) United States
(12) Patent Application Publication
(10) Pub. No.: US 2009/0189643 A1
(43) Pub. Date: Jul. 30, 2009

(54) CONSTANT VOLTAGE GENERATING DEVICE

(75) Inventor: Dharmaray M. Nedalgi, Eindhoven (IN)

Correspondence Address: SEED INTELLECTUAL PROPERTY LAW GROUP PLLC, 701 FIFTH AVENUE, SUITE 5400, SEATTLE, WA, 98104-7092, US

(73) Assignee: ST WIRELESS SA, Geneva (CH)

(21) Appl. No.: 12/343,012

(22) Filed: Dec. 23, 2008

Related U.S. Application Data
(63) Continuation-in-part of application No. PCT/IB2007/052296, filed on Jun. 15, 2007.

(30) Foreign Application Priority Data
Jun. 26, 2006 (EP) 06116067.7

(51) Int. Cl. H03K 19/20; H03K 19/094; H03K 19/003

(52) U.S. Cl. 326/119; 327/576; 326/15; 326/103

(57) ABSTRACT

A constant voltage generator device provides a first and a second transistor having their main current path coupled serially via a common terminal for providing a constant output voltage at the common terminal of said transistors. The device provides one or more potential dividers having a plurality of serially connected resistive elements. A first voltage is obtained from a first combination of resistive elements of the potential divider and a second voltage obtained from a second combination of resistive elements of the potential divider. The first and the second voltages are supplied to the first and the second voltage at the control terminals of the first and the second transistors, respectively.

### BACKGROUND

1. Technical Field

The present disclosure relates to a constant voltage-generating device and, more specifically, relates to a constant voltage generating device for Complementary Metal Oxide Semiconductor (CMOS) circuits, including an inverter utilizing such a constant voltage generating device, and to an integrated circuit implementing a constant voltage generating device.

2. Description of the Related Art

Voltage-coupling is known in the art. It is highly desirable that voltage-coupling have no effect on operation of an electronic circuit or on devices used in the circuit. Electromagnetic interferences, parasitic capacitance, switching of a device, etc., may subject a circuit to a voltage coupling. Voltage-coupling not only slows the operating speed of the circuit but also adds noise. Furthermore, voltage perturbations in a device due to voltage-coupling may cause fatigue or stress and degrade the normal or expected characteristics of the device.

Voltage-coupling raises a serious concern, especially in low power applications of a Complementary Metal Oxide Semiconductor (CMOS) circuit, where a voltage difference across the terminals of a CMOS device is more or less the same as a supply voltage. Furthermore, it is an issue of concern when the operating voltage of a circuit is higher than the tolerable voltage of a device used in the circuit. For example, 65 nm technology provides for low power devices to operate at 2.5 V. A voltage stress over 2.75V impairs their reliability due to effects such as hot carrier degradation or oxide breakdown. However, these devices may require interaction with a circuit (for example Universal Serial Bus (USB) interface (operating voltage 3.3V)), that operates at a higher voltage than 2.75V. In such cases the low power device is provided with a facility for ensuring that the device does not suffer stresses. However, an undesirable voltage-coupling at the device or at the facility may result in malfunctioning or breakdown of the device or circuit. Therefore, voltage-coupling is an undesirable phenomenon in an electronic circuit and measures are required to eliminate or reduce the effects of voltage-coupling.

FIG. 1 shows an example of a cascoded inverter 100. The requirement of a constant voltage and the effect of voltage coupling are explained with reference to this circuit. The inverter has a facility 110 for avoiding voltage stress. The inverter 100 has transistors 120 and a transistor 140 connected in series through the facility 110. The facility 110 includes a transistor 111 and a transistor 112 both transistors connected serially. The control terminals 113, 114 of the transistors 111 and 112 are supplied with a constant voltage. A power supply (VDD and VSS) is connected to the transistors 120 and 140 as shown in FIG. 1. Providing the facility 110 ensures that a voltage difference across any two terminals of the transistor 120 or 140 does not exceed an identified voltage thereby avoiding situations that may cause stress to the transistor(s). For maintaining the voltage difference across the terminals of a transistor below a predetermined value, it is important that a constant voltage is supplied at the control terminals 113, 114 of the transistors 120 and 140. However, in due course of operation, toggling of the transistors 120, 140 often results in a voltage-coupling at the control terminal 113, 114 of the transistors 120 or 140. This voltage coupling is a serious threat to the circuit operation and to the transistors therein because of the reasons discussed earlier. Therefore such circuits require a constant voltage generating device, which ensures that a voltage coupling is immediately eliminated.

FIG. 2 and FIG. 3 show conventional constant voltage generating circuits 200, 300 that may be used for the inverter 100. In these circuits a constant voltage is generated using potential dividers 210, 310. In these circuits a DC current flows through the resistors 211, 212, 311. To keep the current low it is necessary to increase the resistance value of these resistors as much as possible (on the order of mega-ohms). However, if the resistance values are increased, then the output voltage becomes highly susceptible to the noises (voltage-coupling) that are produced during the circuit operations. A capacitor 213, 313 is often provided for reducing the effect of noises at the output voltage of the circuit. This capacitor 213, 313 is referred to as a decoupling capacitor. Fabricating such decoupling capacitors is expensive and requires a large area on the chip.

Japanese Patent application number S54-53483 describes a power supply circuit for use in a liquid crystal. FIG. 4 shows the power supply 400 according to this patent application. For a detailed description of the operation of the circuit, reference is made to the Japanese patent application. The limitations of this circuit are discussed hereinafter.

The power supply circuit shown in FIG. 4 requires a large silicon area. The circuit 400 uses operational amplifiers 410 that consume a static current. Consequently, the circuit is unsuitable in low power applications. Further, the operational amplifiers 410 are used as comparators that turn the transistors 420 on or off when a voltage difference across their inputs exceeds a threshold voltage. The operational amplifier 410 inherently delays a response to any change observed at its input. This delay is referred to as a response time of the operational amplifier 410. Because of this response time, switching of any of the transistors 420 in response to a change at the inputs is at least delayed by a response time of the operational amplifier 410. In addition, the transistors 420 also require a response time for turning on or turning off (to reach from cut-off to saturation region of operation or vice-versa). The response time of the operational amplifier 410 and the response time of the transistor 420 together determine a response time of the circuit 400. That is, the circuit 400 will delay a response to any voltage-coupling at its output by a time equal to the response time of the circuit 400. This delay is not desirable in high-speed circuits.

Furthermore, the operational amplifiers 410 keep the transistors 420 in an off state (in cut-off region) until the voltage difference exceeds a threshold value. Therefore, during this time when the voltage difference is still below the threshold value, the circuit 400 is not protected against voltage-coupling. The situation turns worse if within the response time of the circuit 400, the circuit 400 suffers both a positive (increase in voltage at the common terminal 430, 431 of the transistors 420 due to voltage-coupling) and a negative voltage-coupling (decrease in voltage at the common terminal 430, 431 of the transistors 420 due to voltage-coupling). For example, if the common terminals 430, 431 of the transistors 420 are subjected to a voltage-coupling due to a clock signal having a clock cycle duration of less than or equal to the response time, then the voltage at the common terminals 430, 431 oscillates with the clock signal instead of remaining at a stable voltage. This defeats the main purpose of having the circuit 400, and it makes the circuit 400 unsuitable for real-time and high-speed applications.

Therefore, it is desirable to have a circuit that does not have the above and other limitations.

### BRIEF SUMMARY

According to aspects of the disclosure, a device is provided that includes a first transistor and a second transistor having their main current paths coupled serially via a common terminal, and at least a potential divider having a plurality of serially connected resistive elements for providing a first voltage obtained from a first combination of resistive elements of the potential divider and a second voltage obtained from a second combination of resistive elements of the potential divider for supplying the first and the second voltage at control terminals of the first and the second transistors respectively.

In this way a constant voltage generator is obtained. Each of the transistors includes a first and a second conducting terminal. The first conducting terminal of the first transistor is connected to a power source terminal. The first conducting terminal of the second transistor is connected to a power sink terminal. The second terminals of the transistors are coupled together to form a set of serially connected transistors. The first voltage supplied to the control terminal of the first transistor is selected such that when a threshold-voltage of the first transistor is subtracted from the first voltage it provides a value corresponding to the output voltage.

Further, the second voltage is selected such that when a threshold-voltage of the second transistor is added to the second voltage it provides a voltage value corresponding to the output voltage. When a voltage-coupling (or any other reason(s)) causes an accumulation of additional charge at the common terminal of the transistors, hence increasing the output voltage, the potential difference between the common terminal and the control terminal of the second transistor increases. This increase in potential difference results in a reduction of resistance of the second transistor. The reduction in the resistance of the second transistor allows the additional charge to sink into the power sink terminal through the second transistor. The resistance of the second transistor continuously increases during the period that the additional charge sinks into the power sink terminal and reaches a steady state value when the potential difference between the common terminal and the control terminal of the second transistor is a value corresponding to the threshold voltage of the second transistor.

Further, when a voltage-coupling (or any other reason(s)) decreases the output voltage, the potential difference between the common terminal and the control terminal of the first transistor increases. This increase in potential difference results in a reduction of resistance of the first transistor. The reduction in the resistance of the first transistor allows an additional charge to sink from the power source terminal to the common terminal through the first transistor. The resistance of the first transistor continuously increases during the period that the additional charge sinks from the power source terminal and reaches a steady state value when the potential difference between the common terminal and the control terminal of the first transistor is a value corresponding to the threshold voltage of the first transistor.

In a preferred embodiment the first and the second voltages are selected such that the transistors are in a sub-threshold conduction mode and therefore offer a high resistance in a steady state operation of the circuit. This ensures a minimal current flow through the transistors in the steady state and hence provides a power efficient constant voltage generator. Since the transistors are already in sub-threshold conduction mode no response time is required for the transistors to reach from cut-off region to saturation region. This ensures an immediate response to any change observed in the output voltage. Since the transistors obtain the first and the second voltages at the respective control terminals directly from the potential divider the circuit does not require any additional (intermediate) circuitry or transistors.

Hence, the device provides an area efficient circuit. Furthermore, voltage differences across any two terminals of a transistor that exceed the supply voltage are avoided, and therefore no transistor suffers any stress or fatigue. The resistive elements of the potential divider may be implemented using resistances, transistors, diodes or any combination thereof. In an embodiment the first and the second transistors are complementary conductivity type transistors.

According to certain aspects of the disclosure, an inverter is provided having the above-defined device. The inverter includes a first plurality of transistors having their main conducting path connected in series via a protection facility, and said facility is coupled with the common terminal of the device. The protection facility includes one or more transistors, the transistor having a control terminal, and the control terminal of the transistor is coupled to the common terminal of the device.

This embodiment of the disclosure provides an inverter that has a protection circuit. The protection circuit receives a constant voltage from the device. Supplying a constant voltage to the protection circuit makes certain that a substantially constant potential difference is maintained across any two terminals of the protection facility and thereby ensures that none of the transistors of the inverters are under stress due to any voltage coupling or voltage variations.

In an embodiment, the device may be provided with an integrated circuit, the integrated circuit having one or more input/output pins and a processing unit.

According to this aspect, the device may be included with an integrated circuit. The device may precede or follow the input/output pins. The device may also be included between the processing unit and the input/output pins. The device may also be included within the processing unit.

In accordance with another embodiment of the present disclosure, a circuit is provided, the circuit including a first transistor having a first terminal coupled to a first voltage source, a second terminal connected directly to a first node, and a control terminal; a second transistor having a first terminal coupled to a second voltage source, a second terminal connected directly to the first node, and a control terminal; and a voltage divider circuit coupled between the first and second voltage sources and having first and second outputs coupled respectively to the first and second control terminals of the first and second transistors.

In accordance with another aspect with the foregoing embodiment, the voltage divider is formed from a plurality of series-coupled transistors or resistors.

### BRIEF DESCRIPTION OF THE SEVERAL VIEWS OF THE DRAWINGS

These are other aspect of the disclosure will now be described with reference to accompanying drawings, wherein:

FIG. 1 shows an example of a cascaded inverter;

FIG. 2 and FIG. 3 show conventional constant voltage generators;

FIG. 4 shows a device according to a prior art;

FIG. 5 shows an embodiment of a device according to the present disclosure;

FIG. 6 shows another embodiment of a device according to the present disclosure; and

FIG. 7 shows an inverter according to the present disclosure.

### DETAILED DESCRIPTION

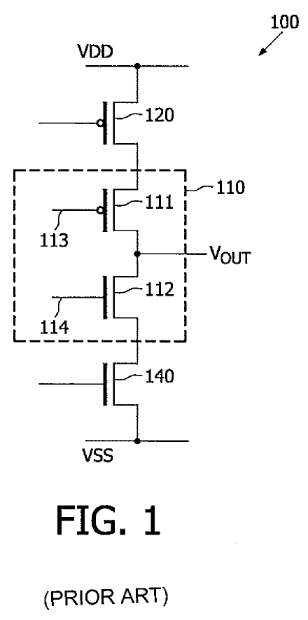

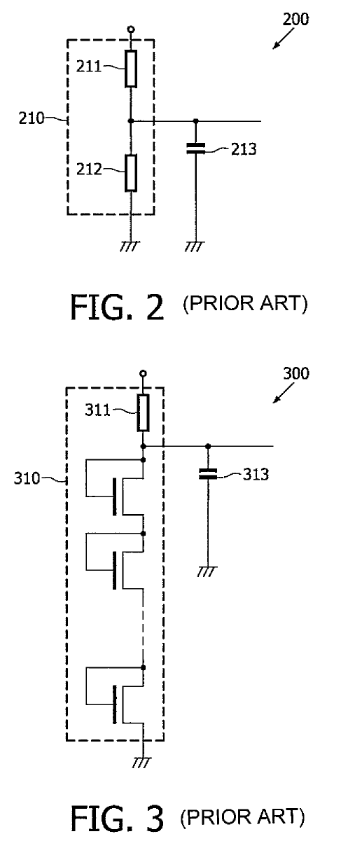

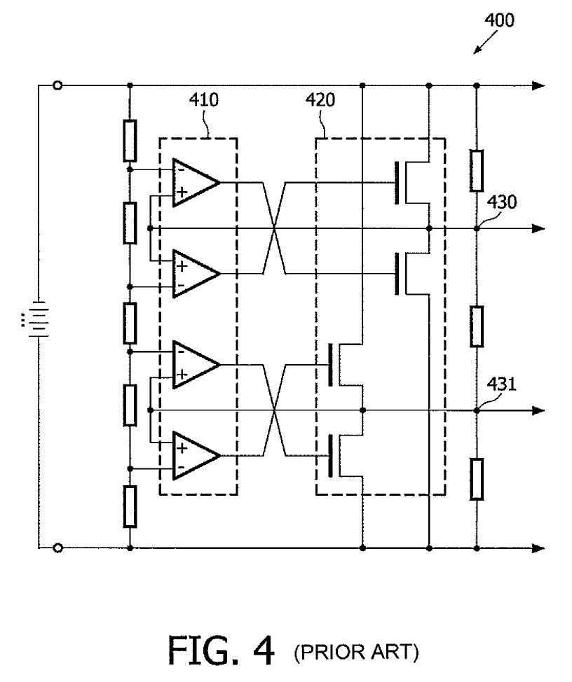

FIGS. 1 to 4 have already been discussed earlier.

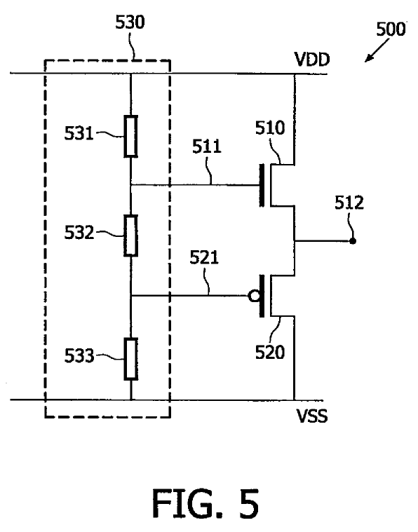

FIG. 5 shows an embodiment of a device 500 according to the present disclosure. The device 500 includes a first transistor 510 and a second transistor 520 having their main current paths coupled serially. The transistors 510 and 520 are of a complementary conductivity type. A node 512 provides an output voltage. The device has a potential divider 530. Said potential divider has a plurality of serially connected resistive elements 531, 532, 533. A first combination of the resistive elements provides a first voltage at the common terminal of resistive elements 531 and 532. The first voltage is supplied to a control terminal 511 of the first transistor 510. A second combination of the resistive elements provides a second voltage at the common terminal of resistive elements 532 and 533. The second voltage is supplied to a control terminal 521 of the second transistor 520. The device 500 is biased using supply terminals VDD and VSS.

The first voltage supplied to the control terminal 511 of the first transistor 510 is selected such that it equals the sum of a threshold-voltage of the first transistor 510 and a desired value for the output voltage at the common terminal 512. Further, the second voltage at the control terminal 521 is selected such that it equals a desired value of the output voltage at the common terminal 512 minus the threshold-voltage of the second transistor.

When a voltage-coupling (or any other reason(s)) causes an accumulation of additional charge at the common terminal 512 of the transistors, this increases the output voltage at 512. Therewith the potential difference between the common terminal 512 and the control terminal 521 of the second transistor increases. This increase in potential difference results in a reduction of resistance of the second transistor 520. The reduction in the resistance of the second transistor 520 allows the additional charge to sink into the power terminal VSS through the second transistor 520. The resistance of the second transistor 520 continuously increases during the sinking of the additional charge into the power terminal VSS and reaches a steady state value when the potential difference between the common terminal 512 and the control terminal 521 of the second transistor 520 reaches a value corresponding to the threshold voltage of the second transistor 520.

Further, when a voltage-coupling (or any other reason(s)) decreases the output voltage 512, the potential difference between the common terminal 512 and the control terminal 511 of the first transistor 510 increases. This increase in potential difference results in a reduction of resistance of the first transistor 510. The reduction in the resistance of the first transistor 510 allows an additional charge to flow from the power terminal VDD to the common terminal 512 through the first transistor 510. The resistance of the first transistor 510 continuously increases during the flow of additional charge from the power terminal VDD and reaches a steady state value when the potential difference between the common terminal 512 and the control terminal 511 of the first transistor 510 is a value corresponding to the threshold voltage of the first transistor.

Further, the first voltage at the control terminal 511 and the second voltages at the control terminal 521 are selected such that transistors 510, 520 are in a sub-threshold conduction mode. In this mode the transistors 510, 520 offer a high resistance in a steady state operation of the circuit 500. This ensures a minimal current flow through the transistors and hence provides a power efficient constant voltage generator. Furthermore, a voltage difference across any two terminals of a transistor never exceeds the supply voltage, and therefore no transistor suffers any stress or fatigue. The resistive elements of the potential divider may be implemented using resistances, transistors, diodes or any combination thereof.

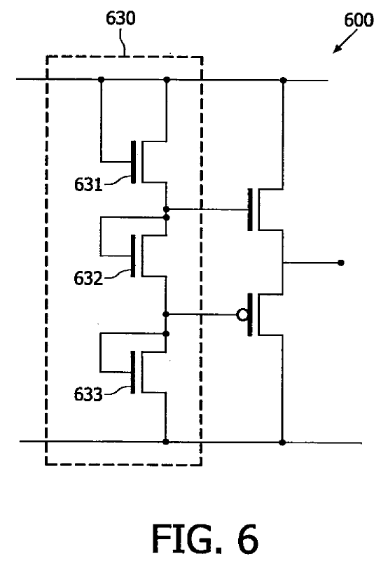

FIG. 6 shows another embodiment 600 of a device according to the disclosure. In this embodiment, the potential divider 630 is realized using diodes 631, 632 and 633. Other embodiments of the device are possible having a potential divider implemented using resistors or diodes or transistors or any combination thereof.

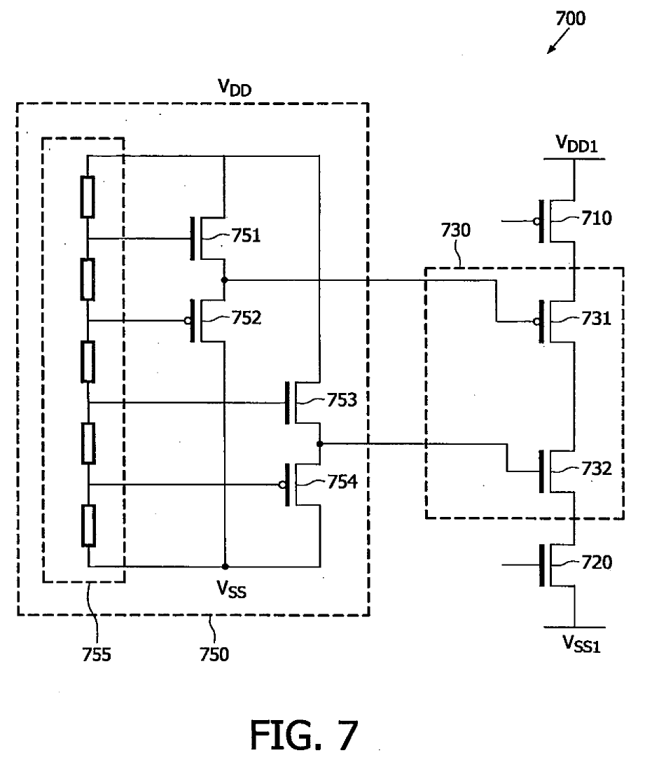

FIG. 7 shows an inverter 700 having a device 750 according to the present disclosure. The inverter 700 comprises a first plurality of transistors 710, 720 connected in series through a protection facility 730. The output of the device 750 is coupled to the protection facility 730. The protection facility 730 comprises transistors 731, 732. The control terminals of these transistors receive the output signals of the device 750. The device 750 comprises potential divider 755, as well as transistors 751, 752, 753 and 754. The control terminals of the transistors 751, 752, 753 and 754 are coupled to the potential divider as shown in FIG. 7. A common terminal of the transistors 751 and 752 provides a first output of the circuit 75, which is coupled to the control terminal of transistor 731. A common terminal of the transistors 753, 754 provides a further output of the circuit 750 that is coupled to the transistor 732. The device 750 is biased using supply VDD and VSS. The transistor 710 and 720 may also be biased using the same supply VDD and VSS. Alternatively a different supply VDD1 and VSS1 may be used to bias the transistors. Coupling the control terminals of transistors 731, 732 to the output of the device 750 ensures that these control terminals receive a substantially constant voltage. Therefore, a substantially constant voltage drop is maintained across any two terminals of any of the transistors of the inverter thereby protecting the inverter from voltage stress caused due to voltage coupling.

The order in the described embodiments of the device of the present disclosure is not mandatory, and is illustrative only. The scope of the disclosure is not limited to the described embodiments. A person skilled in the art may include one or more resistive elements or potential dividers with the circuit and still perform the function of the device. Any such embodiment will fall under the scope of the disclosure and is a subject matter of protection. It should be noted that the above-mentioned embodiments illustrate rather than limit the device, and that those skilled in the art will be able to design many alternative embodiments without departing from the scope of the appended claims. In the claims, any reference signs placed between parentheses shall not be construed as limiting the claim. The word “comprising” does not exclude the presence of elements or steps other than those listed in a claim. The word “a” or “an” preceding an element does not exclude the presence of a plurality of such elements. The device can be implemented by means of hardware comprising several distinct elements, and by means of a suitably programmed computer. The mere fact that certain measures are recited in mutually different dependent claims does not indicate that a combination of these measures cannot be used to advantage.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a first and a second transistor having their main current paths coupled serially via a common terminal; and
at least a potential divider having a plurality of serially connected resistive elements for providing a first voltage obtained from a first combination of resistive elements of the potential divider and a second voltage obtained from a second combination of resistive elements of the potential divider for supplying the first and the second voltage at control terminals of the first and the second transistors respectively.

2. The device of claim 1, wherein said resistive elements comprise resistances, transistors, diodes or any combination thereof.

3. The device of claim 1, wherein said transistors are of a mutually complementary conductivity type.

4. An inverter, comprising:
a device comprising:
a first and a second transistor having their main current paths coupled serially via a common terminal; and
at least a potential divider having a plurality of serially connected resistive elements for providing a first voltage obtained from a first combination of resistive elements of the potential divider and a second voltage obtained from a second combination of resistive elements of the potential divider for supplying the first and the second voltage at control terminals of the first and the second transistors respectively; and
a first plurality of transistors having their main conducting path connected in series via a protection facility, and wherein said facility is coupled with the common terminal of the device.

5. The inverter of claim 4, wherein said protection facility includes at least one transistor, wherein the at least one transistor includes a control terminal that is coupled to the common terminal of the device.

6. An integrated circuit, comprising:
a device, comprising:
a first and a second transistor having their main current paths coupled serially via a common terminal; and
at least a potential divider having a plurality of serially connected resistive elements for providing a first voltage obtained from a first combination of resistive elements of the potential divider and a second voltage obtained from a second combination of resistive elements of the potential divider for supplying the first and the second voltage at control terminals of the first and the second transistors respectively; and
one or more input/output pins and a processing unit.

7. The integrated circuit of claim 6, wherein said resistive elements comprise resistances, transistors, diodes or any combination thereof.

8. The integrated circuit of claim 6, wherein said transistors are of a mutually complementary conductivity type.

9. A circuit, comprising:
a first transistor having a first terminal coupled to a first voltage source, a second terminal connected directly to a first node, and a control terminal;
a second transistor having a first terminal coupled to a second voltage source, a second terminal connected directly to the first node, and a control terminal; and
a voltage divider circuit coupled between the first and second voltage sources and having first and second outputs coupled respectively to the first and second control terminals of the first and second transistors.

10. The circuit of claim 9, wherein the voltage divider circuit comprises a plurality of series-coupled resistors.

11. The circuit of claim 9, wherein the voltage divider circuit comprises a plurality of transistors having their main current path coupled serially with a control terminal of each transistor coupled to the current path.
